(19) United States
(12) Patent Application Publication
(10) Pub. No.: US 2003/0047666 A1
(43) Pub. Date: Mar. 13, 2003

(54) Three-dimensional signature control process and apparatus with military application

(76) Inventor: Ray M. Alden, Raleigh, NC (US)

Correspondence Address: Ray M. Alden, 808 Lake Brandon Trail, Raleigh, NC, 27610, US

(21) Appl. No.: 10/266,371

(22) Filed: Oct. 8, 2002

Related U.S. Application Data
(63) Continuation-in-part of application No. 09/757,053, filed on Jan. 8, 2001.
(63) Continuation-in-part of application No. 09/970,368, filed on Oct. 2, 2001.
(63) Continuation-in-part of application No. 10/132,331, filed on Apr. 24, 2002.

(51) Int. Cl. H01L 27/00

(52) U.S. Cl. 250/208.1

(57) ABSTRACT

The invention described herein represents a significant improvement for the concealment of objects and people. The three-dimensional signature control architecture described herein uses an array of individual reflective pixels and an array of reflecting secondary mirrors in conic section. These two basic elements work in conjunction to collect electromagnetic energy, condense and segment it according to horizontal plane and original trajectory, collimate it, reflect it to along a parallel (to the original) trajectory, expand it, and emit it at an extension point of its original trajectory and in the same horizontal plane. An individual pixel consisting of a cylinder lens and a reflective concave mirror. The reflecting secondary mirrors forming a conic section of arrayed convex mirrors to receive light from pixels and reflect it to other pixels. The light which was incident on a first side of the object traveling at a series of respective trajectories is thus redirected and exits on at least one second side of the object according to its original incident trajectories. It captures and emits light which mimics trajectory, color, and intensity in many concurrent directions such that multiple concurrent observers, can “see through” the object to the background.

### CROSS REFERENCE TO RELATED APPLICATIONS

This application is a Continuation-In-Part of application Ser. No. 09/757,053 filed Jan. 8, 2001, of Ser. No. 09/970,368 filed Oct. 2, 2001, and of Ser. No. 10/132,331 filed on Apr. 24, 2002.

### BACKGROUND FIELD OF INVENTION

The field of invention relates to three dimensional signature management or 3-D signature control technology (also known as cloaking) which has been described by the present inventor in related applications cross referenced in the present application. Some advantages can be gained from adapting these prior architectures to provide a system which passively conducts electromagnetic from multiple concurrent background perspectives and presents them to multiple concurrent observer positions as described in the related applications while omitting the need for a conductive fiber-optic or light pipe.

This continuation in part describes a transmissive 3-D camouflaging architecture replaces the internal reflective means of the related applications (fiber optics or light pipes) with an external reflective means (mirrors in series).

### BACKGROUND DESCRIPTION OF PRIOR INVENTION

The concept of rendering objects invisible has long been contemplated in science fiction. Works such as Star Trek and The Invisible Man include means to render objects or people invisible. Prior Art illustrates the active camouflage approach used in U.S. Pat. No. 5,220,631. This approach is also described in “JPL New Technology report NPO-20706” August 2000. It uses an image recording camera on the first side of an object and a image display screen on the second (opposite) side of the object. This approach is adequate to cloak an object from one known observation point but is inadequate to cloak an object from multiple observation points simultaneously. In an effort to improve upon this, the prior art of U.S. Pat. No. 5,307,162 uses a curved image display screen to send an image of the cloaked object's background and multiple image recording cameras to receive the background image. All of the prior art uses one or more cameras which record two-dimensional pixels which are then displayed on screens which are themselves two-dimensional. These prior art systems are inadequate to render objects invisible from multiple observation points. Moreover, they are too cumbersome for practical deployment in the field.

The process of collecting pictorial information in the form of two-dimensional pixels and replaying it on monitors has been brought to a very fine art over the past one hundred years. More recently, three-dimensional pictorial “bubbles” have been created using optics and computer software to enable users to “virtually travel” from within a virtual bubble. The user interface for these virtual bubble are nearly always presented on a two-dimensional screen, with the user navigating to different views on the screen. When presented in a three-dimensional user interface, the user is on the inside of the bubble with the image on the inside of the bubble's surface.

Also known in the prior art are “three-dimensional” displays which attempt to display a first image stream to the right eye of observers and a second image stream to the left eye of observers. In actuality two streams can only achieve stereoscopic displays. Specifically, stereoscopic displays present the same two image streams to all multiple concurrent observers and are therefore not truly three-dimensional displays. The three-dimensional display as implemented using the technology disclosed herein provides many concurrent image streams such that multiple observers viewing the display from unique viewing perspectives each see unique image streams.

Using concurrent image receiving three-dimensional “cameras” and image sending “displays”, the present invention creates a three-dimensional virtual image bubble on the outside surface of an actual three-dimensional object. By contrast, observers are on the outside of this three-dimensional bubble. This three-dimensional bubble renders the object within the bubble invisible to observers who can only “see through the object” and observe the object's background. The present invention can make military and police vehicles and operatives invisible against their background from nearly any viewing perspective. It can operate within and outside of the visible range.

### BRIEF SUMMARY

The invention described herein represents a significant improvement for the concealment of objects and people. Thousands of directionally segmented light receiving pixels and directionally segmented light sending pixels are affixed to the surface of the object to be concealed. Each receiving pixel segment receives colored light from one portion or trajectory of the background of the object. Each receiving pixel segment is positioned such that the trajectory of the light striking it determines the angles at which it is reflected such that it reemerges at the proper position and trajectory.

The three-dimensional signature control architecture described herein uses an array of individual reflective pixels and an array of reflecting secondary mirrors in conic section. These two basic elements work in conjunction to collect electromagnetic energy, condense and segment it according to horizontal plane and original trajectory, reflect it to along a parallel (to the original) trajectory, expand it, and emit it at an extension point of its original trajectory in the same horizontal plane. An individual pixel consisting of a cylinder lens and a reflective concave mirror. The reflecting secondary mirrors forming a conic section of arrayed convex mirrors to receive light from receiving pixels and reflected it to sending pixels.

Objects and Advantages

Accordingly, several objects and advantages of the present invention are apparent. It is an object of the present invention to provide a three-dimensional receiver of light. It is an advantage of the present invention to provide a three-dimensional sender of light. It is an object of the present invention to provide an integration architecture to integrate the three-dimensional light receiver function together with the three-dimensional light sender function for passive concurrent real-time operation. It is an object of the present invention to create a three-dimensional virtual image bubble surrounding or on the surface of objects and people. Observers looking at this three-dimensional bubble from any viewing perspective are only able to see the background of the object through the bubble. This enables military vehicles and operatives to be more difficult to detect and may save lives in many instances. Likewise, police operatives operating within a bubble can be made difficult to detect by criminal suspects. The apparatus is designed to be always on. The apparatus is designed to consume no energy. It is rugged, reliable, and light weight. The lens structures can be made from transparent armor. It has relatively few parts. It efficiently redirects light with acceptable losses. It works across a wide range of polychromatic electromagnetic energy. Pixels are duplex, they both send and receive EM. The system does not need to know an enemy's position to be effective. The system conceals objects and people from multiple concurrent observers each located in different positions. No computer processor or electronics are required. It provides very high resolution.

Further objects and advantages will become apparent from the enclosed figures and specifications.

### DRAWING FIGURES

FIG. 1 illustrates a single 3-D reflective pixel in top profile view.

FIG. 2 illustrates a variety of cylinder lens designs for the single pixel of FIG. 1.

FIG. 3 illustrates a pixel reflector's relationship with a first secondary reflector.

FIG. 4a depicts front view of an array of reflective pixels.

FIG. 4b illustrates a single column of 3-D reflective pixels.

FIG. 5 illustrates a 3-D reflective pixel column's working relationship with some secondary reflectors.

FIG. 6 illustrates a complete 3-D reflective pixel signature control apparatus and process of the present invention.

### DETAILED DESCRIPTION OF THE INVENTION

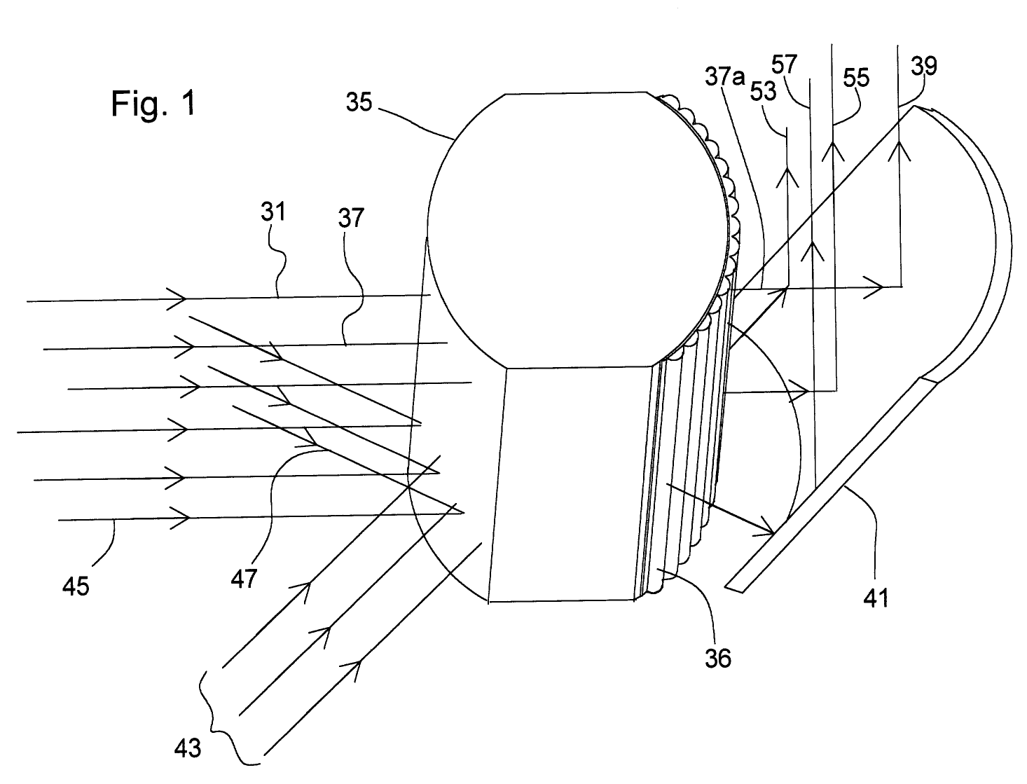

FIG. 1 illustrates a single 3-D reflective pixel in profile view. The single pixel consists of two elements. The first pixel element being a cylinder lens 35. 35's focal length is equal to its diameter. The dimensions of the 3-D reflective pixel are variable heights greater or lesser than one inch are possible and operationally practicable. The following calculation describes of a non-gradient cylinder lens at one wavelength.

n1/s1+n2/s′1=(n2−n1)/R1

set n1=1 (refractive index for air)

set n2=1.5 (refractive index for a median wavelength)

set s′1=2R1 (s′1 being the focal length caused by the first surface and R1 being the cylinder lens radius)

set s1=infinity (object distance)

Therefore, by substitution, the focal length (s′1) caused by the first surface equals 6 units and the radius (R1) equals 3 units. Thus incoming electromagnetic radiation with an object focus at infinity is brought to a focal point (by the first surface) just at the second surface of the cylinder lens. Affixed to the rear surface of 35 is a lenticular array 36. 36 is manufactured from a material transparent in the wavelengths of interest and selected so as to minimize chromatic aberration within the system. These two lens elements thus forming a lens system which compresses the horizontal plane of incoming EM into a number of beams of outgoing EM which respectively reside in the same said horizontal planes.

The second pixel element being a concave mirror 41 conic section with a forty five degree attitude. The mirror comprising a rigid material. The reflective surface of the 35 being on the side of the mirror adjacent to the 35. Said conic section sharing an axis with the 35 such that all points on the reflective surface of the mirror reside at a forty five degree angle relative to rays emitted from the 35 at a normal to its (35s) surface. The 35 and the 41 being comprised of materials conducive to respectively refracting and reflecting desirable electromagnetic energy in the visible and/or non-visible wavelengths.

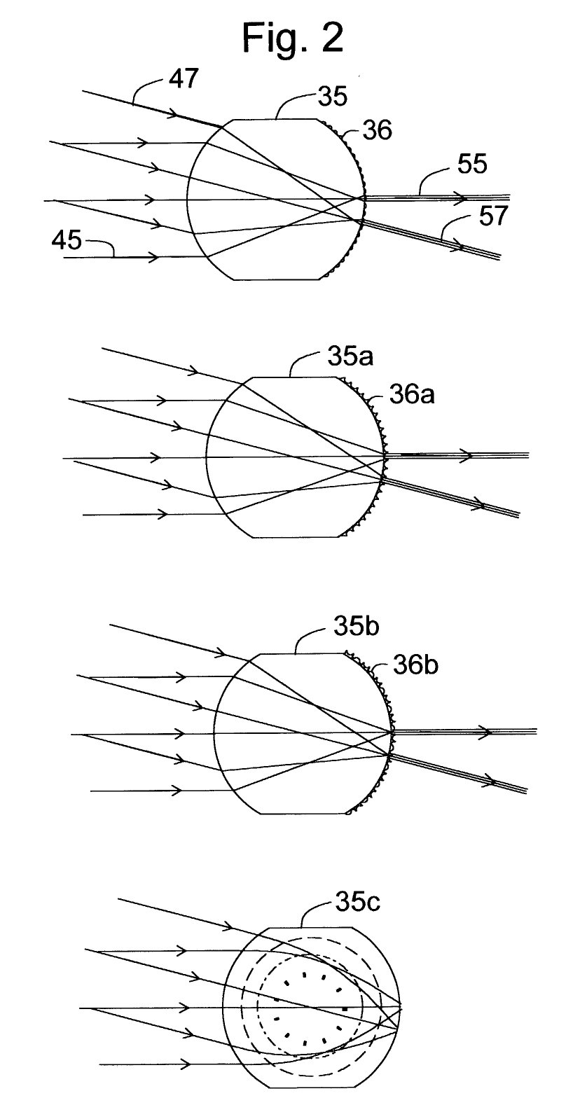

FIG. 2 illustrates a variety of cylinder lens designs for the single pixel of FIG. 1. The 35 cylinder lens has no gradient refractive. It can be manufactured from transparent armor manufactured and molded by Simula Safety Systems of Phoenix, Ariz. Affixed to its rear surface is a calenderer plastic array of convex lenticular lenses 36a. The 35 is manufactured such that its focal length (for a median wavelength) from the first surface is less than or equal to its diameter.

A first alternate cylinder lens 35a has no gradient. It can be manufactured from transparent armor manufactured and molded by Simula Safety Systems of Phoenix, Ariz. Affixed to its rear surface is a calenderer plastic array of concave lenticular lenses 36a. The 35a is manufactured such that its focal length (for a median wavelength) from the first surface is greater than its diameter.

A second alternate cylinder lens 35b has no gradient. It can be manufactured from transparent armor manufactured and molded by Simula Safety Systems of Phoenix, Ariz. Affixed to its rear surface is a calenderer plastic array of concave, and convex lenticular lenses 36b. The 35b is manufactured such that its focal length (for a median wavelength) from the first surface is equal to its diameter.

A fourth alternate cylinder lens 35d has no gradient. It can be manufactured from transparent armor manufactured and molded by Simula Safety Systems of Phoenix, Ariz. It is manufactured such that its focal length (for a median wavelength) from the first surface is equal to its diameter. The equation listed under FIG. 1 describes the first surface of this lens.

A third alternate cylinder lens 35c having a radial axis gradient (the refractive index varies according to position such that the highest refractive index is along the axis of the cylinder lens and the lowest refractive index is a cylinder closest to the surface of the cylinder lens). The 35c enables parallel rays in a horizontal plane to be compressed into a beam when the focal length from the first surface is approximately equal to its diameter. Gradient index cylinder lenses are suitable for this application because they can optimize performance across a range of wavelengths while minimizing chromatic aberration. Producers of gradient index lenses include Lightpath Technologies and Hikari Glass.

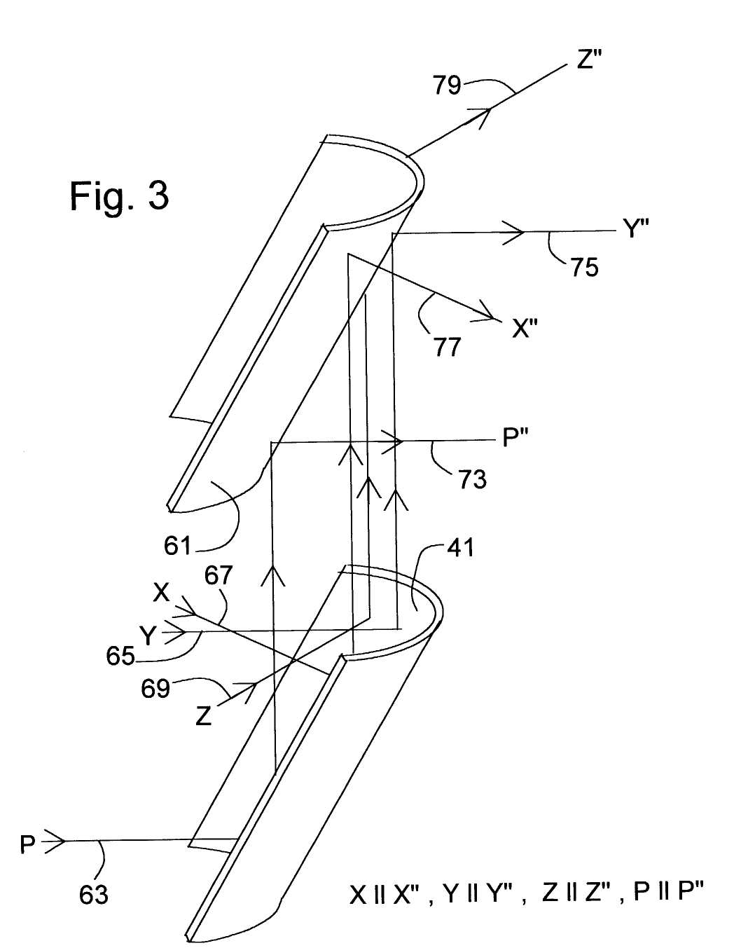

FIG. 3 illustrates a pixel reflector's relationship with a first secondary reflector. The 41 single mirror having been described in FIG. 1. A first secondary mirror 61 comprises a conic section whereby the convex surface of said conic section is comprised of materials reflective in desired wavelengths. A vertical line (a line parallel to the center axis of the 61 conic section) drawn through any section of both the 61 and the 41 will subtend a forty five degree angle (with the respective reflective surface of each) which resides in the same plane as electromagnetic energy which passes through the axis of 35.

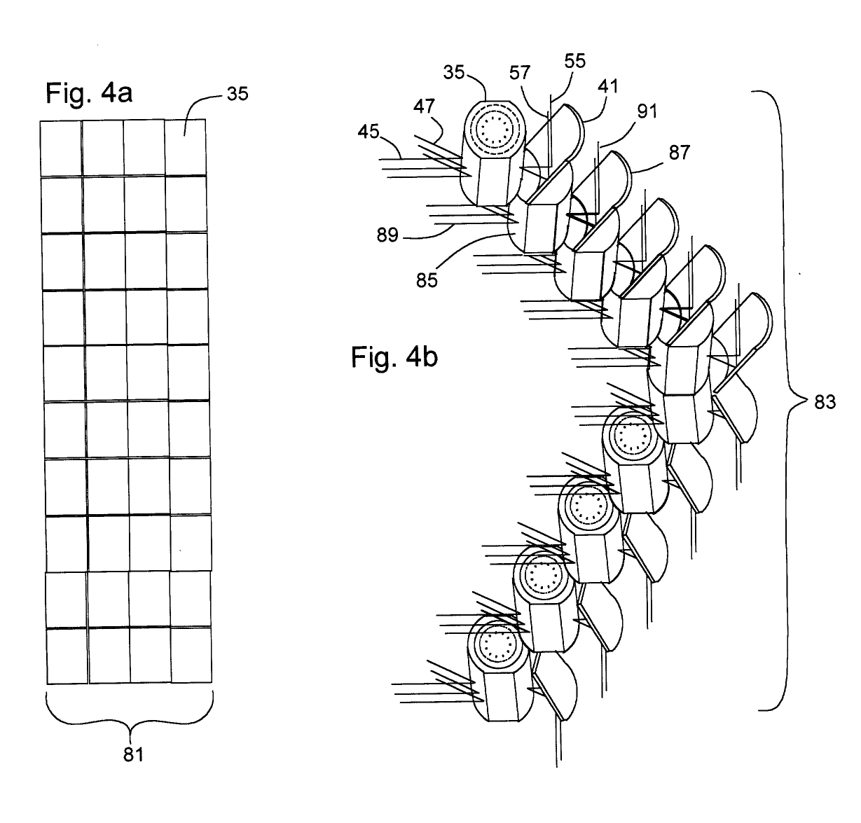

FIG. 4a depicts the front view of an array of reflective pixels. 35 being the front surface of a cylinder lens single reflective pixel of FIG. 1. Said single pixel being arrayed with and affixed to many similar reflective pixels to form a pixel array 81 covering the surface of an asset to be concealed.

FIG. 4b illustrates a single column of 3-D reflective pixels 83 when viewed from the top and side. The 35 with 41 comprising one pixel and being affixed to a second reflective pixel cylinder lens 85 which is identical to 35. 85 is connected to a second reflective pixel mirror 87 which is identical to 41. Note that the 85 has an axis that is pushed back from that of 35. Like wise the 87 is pushed back relative to 41. Each lower tier is similarly backed off the higher layer's axis by a distance equal to the height of the 41.

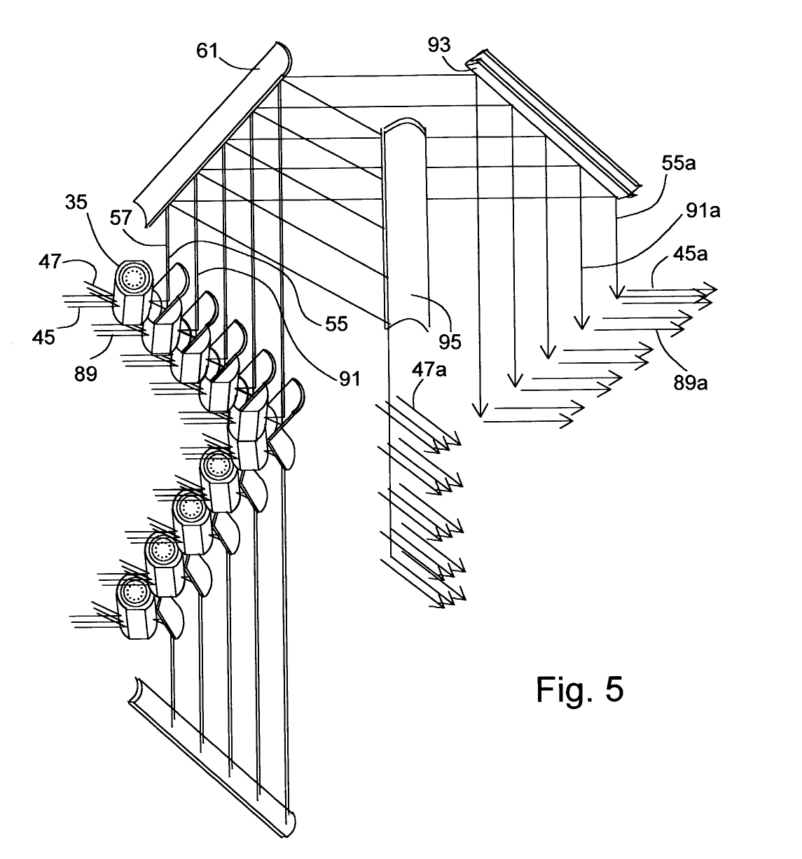

FIG. 5 illustrates a 3-D reflective pixel column's working relationship with some secondary reflectors. The elements of FIG. 4b are present in addition to a second secondary reflector 93 and a third secondary reflector 95. 93 and 95 being identical to 61. Each of their axis residing in a circular conic section with a forty five degree slope.

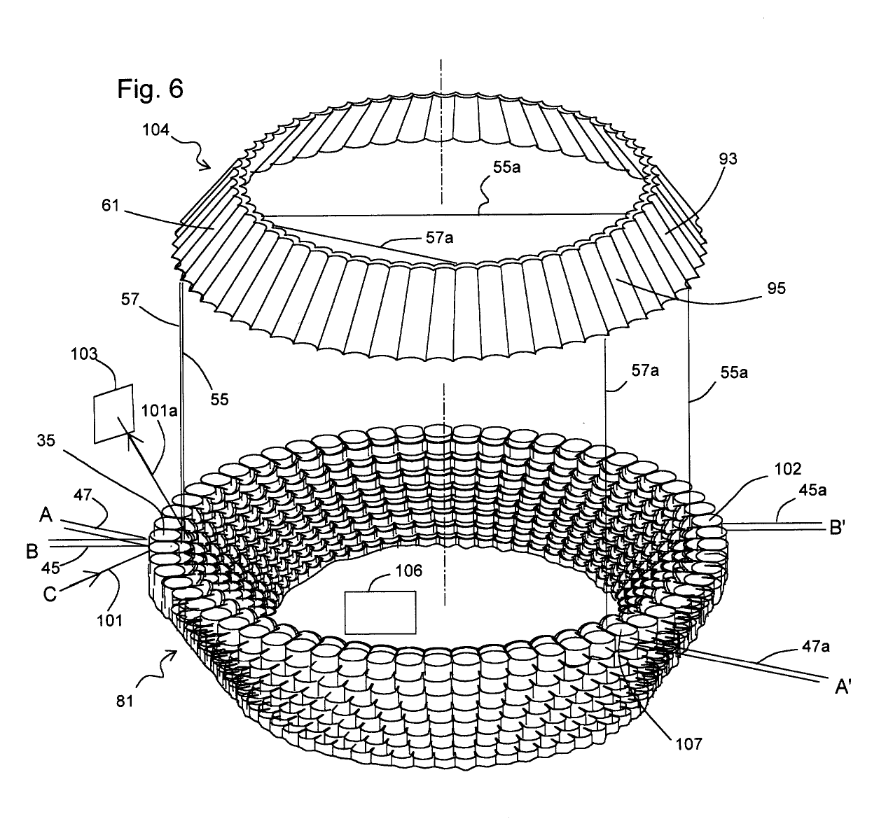

FIG. 6 illustrates a complete 3-D reflective pixel signature control apparatus and process of the present invention. The elements of FIG. 5 are shown integrated into a complete 3-D low observable casing which surrounds an asset 106. Note that the asset is not to scale and that it would normally conform to the shape of the camouflage system (or vice versa). Also the asset would be affixed to the camouflage (or vice versa). An encompassing reflective pixel array 81 includes 35 and a third reflective pixel 102 as well as a fourth reflective pixel 107 and many other pixels. The 102, 107, and 35 each being in the same horizontal plane. An assembled secondary mirror array 104 includes secondary mirrors 61, 93, and 95 together with a number of other secondary mirrors to form a circular conic section with forty five degree slop 104. The surfaces interior to the conic section having reflective properties in desired wavelengths. An electromagnetic absorbing patch 103 is shown. It is manufactured of a material that absorbs electromagnetic energy. In practice the 103 material is used to coat a number of surfaces that otherwise would reflect EM from undesirable trajectories. For example, material coats the surface (not shown) above the 104 and a surface (not shown) below 104. The material also coats the non reflective sides of all the pixel mirrors. Additionally, the asset itself is coated with the 103 material.

Operation of the Invention

FIG. 1 illustrates a single 3-D reflective pixel in profile view. A first ray of polychromatic electromagnetic energy 31 is incident upon 35. A second ray of polychromatic electromagnetic energy 37 is also incident upon 35. Prior to incidence, 35 and 37 being on parallel trajectories and within the same horizontal plane. 35 compresses 31 and 37 along with all other parallel rays within the same horizontal plane 36 then collimates the light which becomes exiting first compressed beam 37a. 37a resides in the same horizontal plane as 37 and has a parallel trajectory prior to being reflected by 41 to become vertical beam 39. Similarly, a second trajectory of EM 47, in a second horizontal plane is incident upon 35, compressed by 35, collimated by 36, reflected vertically by 41 to become a second compressed vertical beam 57. A third trajectory of EM 45 resides in the same plane as 47 but in a non-parallel trajectory. It and all other EM (incident upon 41) parallel to 45 and in its plane are compressed into a beam by 35, collimated by 36, and be reflected by 41 as a third compressed beam 55. A horizontal plan of parallel trajectory EM 43 is in the same horizontal plane as 45 and 47 (but non-parallel in trajectory) similarly is incident upon 35, and compressed to become a fourth compressed beam, collimated by 36, which is reflected by 41 to become fourth vertical beam 53. Note that the position of each beam's incidence upon 41 is a direct function of its original trajectory and its original horizontal plane. The system described effectively sorts and processes EM according to its original trajectory and horizontal plane. This is further described in FIG. 3, FIG. 5, and FIG. 6.

FIG. 2 illustrates a variety of cylinder lens designs for the single pixel of FIG. 1. In a first cylinder lens embodiment, 47 and all parallel EM in its plane are incident upon 35. 35 causes the EM to focus at its extreme rear edge. The EM is then collimated by 36. The EM emerges from the 36 as narrow collimated beam of polychromatic EM 57. The material of 35 and 36 being selected so as to perform achromatically. 57 is parallel to and in the same plane as 47. Likewise 45 and other parallel rays within its plane are incident upon 35. 35 compresses them and 36 collimates them into 55. 55 is parallel to and in the same plane as 45.

35a functions similarly to 35 except that the incident EM is not brought to a focal point within 35a. Instead the EM is converging before it passes through 36a which causes the converging EM to expand into a collimated beam. The material of 35a and 36a being matched so as to provide achromatic performance. 35b has a back focal length equal to its diameter. The 36b has alternately both concave and convex lenticular surfaces such that a wider range of EM can be collimated. EM with a focal point within the 35b being collimated by the convex lenticular lenses and EM with a focal point outside of the 35b being collimated by the concave lenticular lenses.

35c is can be used to further enhance achromatic performance across a wider range of EM within the visible and outside of the visible. It has a gradient index and can be used in conjunction with 36, 36a, or 36b.

FIG. 3 illustrates a pixel reflector's relationship with a first secondary reflector. P beam 63 leaves the 36 (not shown), is reflected by 41 to become vertical, and then is reflected by 61 to become horizontal again as P″ beam 73. Note that 63, and 73 are both in the same vertical plane and they are in parallel horizontal planes. Thus P″ retains its original trajectory information which was present in P. Three additional beams are shown which each share a horizontal plane but differ in trajectory. Note that X, Y, and Z are all incident on 41 in the same horizontal plane and incident upon 61 in a common elevated horizontal plane. The curvature of 61 causes X″, Y″, and Z″ to each respectively continue on trajectories parallel to X, Y, and Z respectively. Thus each collimated beam which emanates from a horizontal plane and that is emitted from 36 retains information relation to its horizontal plane and trajectory throughout the reflective pixel process of the present invention. Note that all arrows can be reversed and in practice EM is always being reflected by this mirror combination in many more planes and trajectories and in both directions.

FIG. 4b illustrates a single column of 3-D reflective pixels. The 85 and 87 pixel is offset to enable EM incident upon 85 to pass vertically by 41 unencumbered. Likewise, each lower tier is offset form the one above it. At the middle of the array, the reverse is true. Thus EM is directed vertically upward unencumbered by the upper pixels and directed vertically downward unencumbered.

FIG. 5 illustrates a 3-D reflective pixel column's working relationship with some secondary reflectors. As previously discussed, 47 EM is compressed and collimated by 35 and 36 and then reflected vertically upward as 57. When 57 is incident upon 61, it is directed at a trajectory parallel with 47 just as 55 is directed by 61 on a trajectory parallel with 45. Thus two beam emanating from the single 35 pixel are directed by a secondary mirror 61 to two different secondary mirrors. 57 is then incident upon 95 which causes it to be reflected down into a reflective pixel (not shown) which spreads it out to be a first spread polychromatic beam 47a. 47a being in the same horizontal plane as 47 and on a continuation of the 47 trajectory. Similarly, 55 is then incident upon 93 which causes it to be reflected down into a reflective pixel (not shown) which spreads it out to be a second spread polychromatic beam 45a. 45a being in the same horizontal plane as 45 and on a continuation of the 45 trajectory. The 89 EM is incident upon lower pixel 85 as described in FIG. 4b. Note that the collimated beams from 85 are incident upon the 61 in a higher plane that those from 35 but as they are reflected again, such as off of 93, they are restored to the proper plane, such as third spread beam 89a. This demonstrates that the horizontal plane information which is retained in this process is temporarily inverted during the reflected process then restored. A lower path for reflected light is also partially shown, if functions identically to the upper half and concurrently.

FIG. 6 illustrates a complete 3-D reflective pixel signature control apparatus and process of the present invention. A C ray 101 enters the 35 pixel from a non-horizontal plane, it is collimated by 36 and reflected by 41 to be a non-vertical beam 101a. 101a and many other EM which can not be concurrently processed by the present architecture must be absorbed when it is incident upon non-optical surfaces. As previously discussed material such as 103 absorbs the vast majority of such stray EM as it is incident on any non-optical surfaces. 47 enters the systems at 35, is reflected vertically by 41 to become 57, is reflected horizontally by 61, is reflected vertically by 93, is reflected horizontally by a pixel mirror connected to a first sending pixel 102, the lens of 102 expanding the EM to become 45a, 45a being in the same horizontal plane and parallel in trajectory to 45. Similarly, 45 enters the systems at 35, is reflected vertically by 41 to become 55, is reflected horizontally by 61, to become 55a, is reflected vertically by 95, is reflected horizontally by a pixel mirror connected to a second sending pixel 107, the lens of 107 expanding the EM to become 47a, 47a being in the same horizontal plane and parallel in trajectory to 47.

Note that all directions are reversible and in practice EM is always concurrently being received, reflected, and emitted by this assembly in many more horizontal planes and trajectories and in both directions than are represented herein.

Conclusion, Ramifications, and Scope

Thus the reader will see that the Three-Dimensional Signature Control Process and Apparatus With Military Application of this invention provides a highly functional and reliable means for using technology to conceal the presence of an object (or asset).

While the above description describes many specifications, these should not be construed as limitations on the scope of the invention, but rather as an exemplification a preferred embodiment thereof. Many other variations are possible.

The description describes a lens, mirror, mirror, mirror, mirror, lens architecture to transport electromagnetic energy from one side of an asset to another side. It is recognized that at least one of these mirrors can easily be eliminated. This may be desirable when a pyramid shaped asset is to be concealed. Eliminating a mirror requires mirror angles other than those specified herein.

It is recognized that other lens and prism structures can intervene in combinations other than that specified herein.

The specification describes a circular arrangement of pixels and secondary mirrors. Many other shapes are possible. No known constraints on the shapes of assets to be concealed exist.

It is possible to substitute other lenses for the cylinder lenses, for example ball lenses or lenticular lenses. Also different combinations of lenses can be constructed to improve achromatic beam formation.

The specification starts with an object light at infinity, other object focus lengths are possible and may at times be desirable.

To achieve achromatic refraction, different lens combinations may be used in place of those specified herein.

Lenses which enable wide angle light segmentation at the pixel level can be designed in many configurations and in series using multiple elements, shapes and gradient indices.

What is claimed:

1. A means for concealing an object comprising a means for receiving a light beam on a first side of an object at a trajectory and for reflecting it to a second side of said object, where it emerges at an extension of the same said trajectory.

2. A camouflaging system comprising:
a first lens,
a second lens,
a third lens,
and a reflecting system,
whereby electromagnetic energy incident upon said first lens is collimated into at least two electromagnetic energy columns, whereby a first electromagnetic energy column is reflected by said reflecting system before emerging from a second lens and whereby said second electromagnetic energy column is reflected by said reflecting system before emerging from said third lens.

3. A method for concealing the presence of an object comprising the steps of:
providing a plurality of lenses,
providing a plurality of mirrors,
whereby electromagnetic energy incident upon a first lens is collimated into at least two electromagnetic energy columns, whereby a first electromagnetic energy column is reflected by at least two mirrors before emerging from a second lens and whereby a second electromagnetic energy column is reflected by at least two mirrors before emerging from a third lens.
